(19) United States
(12) Patent Application Publication
(10) Pub. No.: US 2021/0042204 A1
(43) Pub. Date: Feb. 11, 2021

(54) TESTING APPARATUS, TESTING SYSTEM, AND NON-TRANSITORY TANGIBLE MACHINE-READABLE MEDIUM THEREOF FOR TESTING TOUCH MOBILE DEVICES

(71) Applicant: ISCOOLLAB CO., LTD., Taipei City (TW)

(72) Inventors: Yan-Mei JIANG, Taipei City (TW); Yu-Shan WU, Taipei City (TW)

(21) Appl. No.: 16/683,258

(22) Filed: Nov. 13, 2019

(30) Foreign Application Priority Data
Aug. 5, 2019 (TW) 108127749

(51) Int. Cl. G06F 11/273; G06F 11/263; G06F 11/36; G06F 11/277

(52) U.S. Cl. CPC G06F 11/2733; G06F 11/2635; G06F 11/277; G06F 11/3684; G06F 11/3696

(57) ABSTRACT

A testing apparatus, testing system, and non-transitory tangible machine-readable medium thereof are provided. The testing apparatus includes a first transmission interface, a second transmission interface, a storage, and a processor, wherein the processor is electrically connected to the first transmission interface, the second transmission interface, and the storage. The storage stores a test procedure, wherein the test procedure includes a test item. The storage also stores a piece of expected information corresponding to the test item. The processor reads the test item of the test procedure. The processor determines a test result of a touch mobile device regarding the test item according to the piece of expected information and at least one of a test datum received from the touch mobile device by the first transmission interface and a feedback signal received from a motor controller by the second transmission interface.

### PRIORITY

This patent application claims priority to Taiwan Patent Application No. 108127749 filed on Aug. 5, 2019, which is hereby incorporated by reference in its entirety.

### FIELD

The present invention relates to a testing apparatus, a testing system, and a non-transitory tangible machine-readable medium thereof. Specifically, the present invention relates to a testing apparatus, a testing system, and a non-transitory tangible machine-readable medium thereof for testing touch mobile devices.

### BACKGROUND

With the rapid development of the science and technology, various touch mobile devices (e.g. mobile phones, tablet computers, notebook computers) have become quite popular, and various applications (APPs) running on the touch mobile devices have also been increased rapidly. Both manufacturers of touch mobile devices and developers of applications need to carry out functional testing on physical touch mobile devices after developing their products. Manufacturers of touch mobile devices have the need to test whether necessary software (e.g., Wi-Fi and hotspot) can function normally on the newly assembled touch mobile devices. Due to the diversity of touch mobile devices, developers of applications have the need to test whether their products can operate normally on various brands and models of touch mobile devices.

Presently, the common practice in the industry requires a programmer to write a test program in advance. In the testing phase, a testing apparatus executes the test program, an external camera is used to capture an image regarding what is shown on the display of a touch mobile device under test, and then a result regarding whether the touch mobile device passes a certain test item is determined according to the captured image. However, the qualities of the images captured by an external camera are severely affected by the environmental light source during the test and, hence, the aforesaid conventional testing approach usually provides test results of low accuracy. Accordingly, there is an urgent need for an automatic testing technology that will not be affected by the environmental light source and can provide test result of high accuracy.

### SUMMARY

The disclosure includes a testing apparatus. The testing apparatus can comprise a first transmission interface, a second transmission interface, a storage, and a processor, wherein the processor is electrically connected to the first transmission interface, the second transmission interface, and the storage. The storage stores a test procedure, wherein the test procedure comprises a test item. The storage further stores a piece of expected information corresponding to the test item. The processor reads the test item of the test procedure. The processor determines a test result of a touch mobile device regarding the test item according to the piece of expected information and at least one of a test datum received from the touch mobile device by the first transmission interface and a feedback signal received from a motor controller by the second transmission interface.

The disclosure further includes a testing system, wherein the testing system can comprise a motor controller, a testing apparatus, a first transmission cable, and a second transmission cable. The testing apparatus stores a test procedure, wherein the test procedure comprises a test item. The testing apparatus further stores a piece of expected information corresponding to the test item. The first transmission cable connects the testing apparatus and a touch mobile device. The second transmission cable connects the testing apparatus and the motor controller. The testing apparatus reads the test item of the test procedure. The testing apparatus determines a test result of the touch mobile device regarding the test item according to the piece of expected information and at least one of a test datum received from the touch mobile device and a feedback signal received from the motor controller.

The disclosure further includes a non-transitory tangible machine-readable medium, which stores a computer program comprising a plurality of codes. The codes are able to perform a testing method when the computer program is loaded into an electronic computing apparatus. The electronic computing apparatus stores a test procedure, wherein the test procedure comprises a test item. The electronic computing apparatus further stores a piece of expected information corresponding to the test item. The testing method comprises the following steps: (a) reading the test item of the test procedure and (b) determining a test result of a touch mobile device regarding the test item according to the piece of expected information and at least one of a test datum received from the touch mobile device by the electronic computing apparatus and a feedback signal received from a motor controller by the electronic computing apparatus.

The testing technology (including at least the apparatus, the system, and the non-transitory tangible machine-readable medium thereof) provided herein performs functional testing on a touch mobile device based on at least one test item included in a test procedure. Generally speaking, for each test item included in a test procedure, the testing technology provided by the present invention determines a test result of a touch mobile device regarding the test item according to a piece of expected information corresponding to the test item and a test datum received from the touch mobile device and/or a feedback signal received from a motor controller.

If the test result regarding whether the touch mobile device passes a test item has to be determined based on an image displayed by the touch mobile device, the testing technology provided by the present invention directly receives a test datum from the touch mobile device and then determines whether the touch mobile device passes the test item according to a test image corresponding to the test datum. Because the testing technology provided by the present invention does not require an external camera to capture an image regarding what is shown on the display of the touch mobile device, the test result will not be affected by the light source of the testing environment. Hence, an accurate and stable test result can be achieved. In addition, the testing technology provided by the present invention can use the same test procedure to test other touch mobile devices of the same brand and model. Thus, automatic functional testing of touch mobile devices can be easily realized.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a schematic view of a testing system 1 of the first embodiment;

FIG. 1B is a schematic view of a testing apparatus 11 of the first embodiment;

FIG. 2 is a schematic view of a testing apparatus 11 of a second embodiment; and

FIG. 3A to FIG. 3C are flowcharts depicting a testing method of a third embodiment.

### DETAILED DESCRIPTION

In the following description, the testing apparatus, the testing system, and the non-transitory tangible machine-readable medium thereof for testing a touch mobile device provided in the present invention will be explained with reference to certain example embodiments thereof. However, these example embodiments are not intended to limit the present invention to any specific environment, applications, examples, embodiments or implementations described in these example embodiments. Therefore, description of these example embodiments is only for purpose of illustration rather than to limit the scope of the present invention.

It should be appreciated that, in the following embodiments and the attached drawings, elements unrelated to the present invention are omitted from depiction. Furthermore, dimensions of elements and dimensional scales among individual elements in the attached drawings are provided only for ease of depiction and illustration, but not to limit the scope of the present invention.

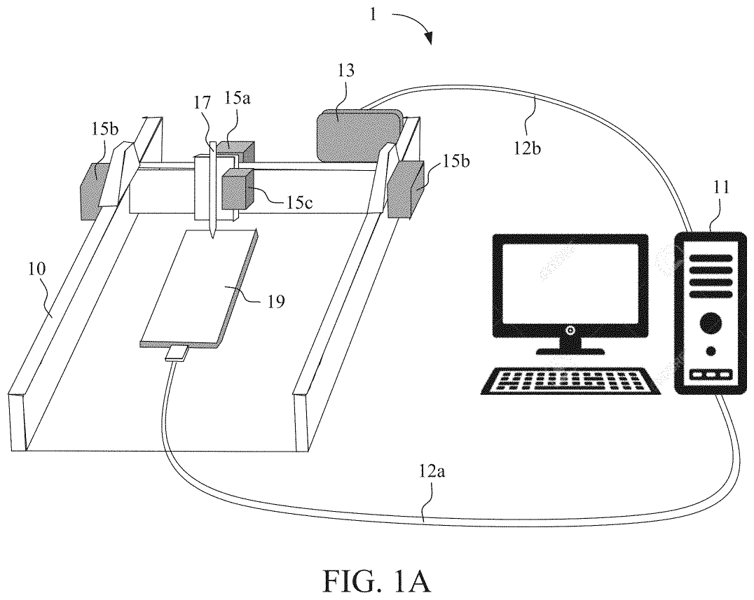

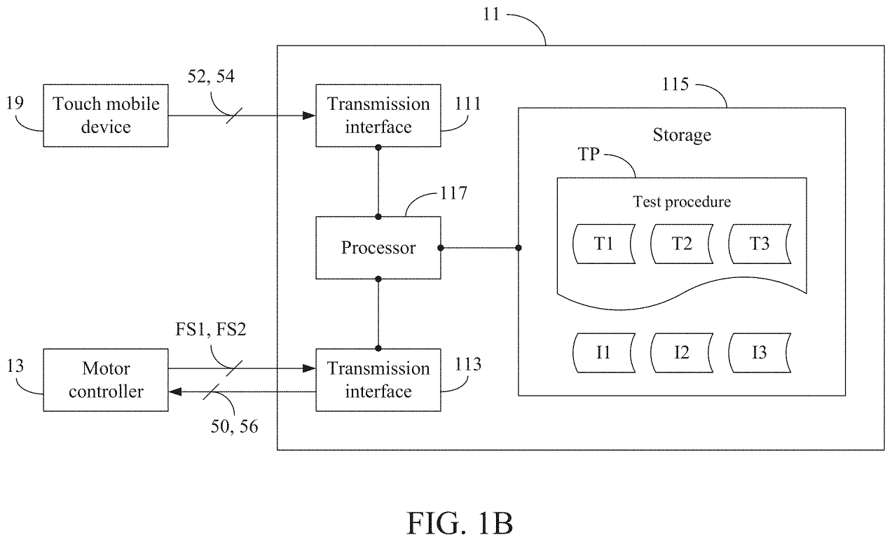

A first embodiment of the present invention is a testing system 1, whose schematic view is depicted in FIG. 1A. The testing system 1 comprises a testing apparatus 11, two transmission cables 12a, 12b, and a motor controller 13. The transmission cable 12a is used for connecting the testing apparatus 11 and a touch mobile device under test (e.g., a touch mobile device 19 placed on a test platform 10 shown in FIG. 1A). Please note that the type of the transmission cable 12a is dependent on the transmission interface of the touch mobile device 19 and the transmission interface of the testing apparatus 11 that the transmission cable 12a is going to connect. For example, the transmission cable 12a may be a Lightning to Video Graphics Array (VGA) adapter, a Universal Serial Bus (USB) interface transmission cable, without being limited thereto. In addition, the transmission cable 12b is used for connecting the testing apparatus 11 and the motor controller 13. Please note that the type of the transmission cable 12b is dependent on the transmission interface of the motor controller 13 and the transmission interface of the testing apparatus 11 that the transmission cable 12b is going to connect. Furthermore, the motor controller 13 may be a device capable of receiving movement control instructions (e.g., G code control instructions) of X-axis, Y-axis, and/or Z-axis and capable of controlling a motor accordingly. For example, the motor controller 13 may be a Computer Numerical Control (CNC) machine tool.

In this embodiment, the testing system 1 further comprises the test platform 10 and an X-axis motor 15a, a set of Y-axis motors 15b, and a Z-axis motor 15c which are disposed on the test platform 10. The motor controller 13 is also disposed on the test platform 10 and is electrically connected to the X-axis motor 15a, the Y-axis motors 15b, and the Z-axis motor 15c. The motor controller 13 can control the X-axis motor 15a, the Y-axis motors 15b, and/or the Z-axis motor 15c to move. The test platform 10 further comprises a stylus 17 (e.g., a digital pen, without being limited thereto), and the position of the stylus 17 may be controlled by the motor controller 13 through the X-axis motor 15a, the Y-axis motors 15b, and/or the Z-axis motor 15c.

It is noted that in other embodiments, the testing system may not comprise the test platform and, instead, may be used with an existing test platform. It shall be additionally noted that the way that the motor controller 13 controls the X-axis motor 15a, the Y-axis motors 15b, and/or the Z-axis motor 15c to move is not the focus of the present invention and, thus, will not be further described herein. Moreover, based on the following descriptions, a person of ordinary skill in the art shall appreciate the way to arrange the test platform 10 to achieve the functional testing provided by the present invention and, thus, the specific way to arrange the test platform 10 will not be further described herein.

The core regarding the operations performed in this embodiment is the testing apparatus 11 and a schematic view thereof is depicted in FIG. 1B. The testing apparatus 11 comprises two transmission interfaces 111, 113, a storage 115, and a processor 117, wherein the processor 117 is electrically connected to the transmission interfaces 111, 113 and the storage 115. The transmission interface 111 may be any interface capable of being connected with the transmission cable 12a (e.g., a video graphics array interface, a USB interface, without being limited thereto) so as to be connected to the touch mobile device 19 through the transmission cable 12a. The transmission interface 113 may be any interface capable of being connected with the transmission cable 12b (e.g., a USB interface, without being limited thereto) so as to be connected to the motor controller 13 through the transmission cable 12b. The transmission interface 113 and the motor controller 13 communicate with each other according to a transmission protocol standard (e.g., an RS-232 control transmission protocol, without being limited thereto). Furthermore, the transmission interface 113 will transmit various control instructions (e.g., G code control instructions, without being limited thereto) to the motor controller 13 so that the motor controller 13 can control the X-axis motor 15a, the Y-axis motors 15b, and/or the Z-axis motor 15c to move accordingly.

The storage 115 may be a memory, a USB disk, a hard disk, a compact disk (CD), a mobile disk, or any other non-transitory storage medium or storage circuit capable of storing digital data and well-known to those of ordinary skill in the art. The processor 117 may be one of various processors, central processing units (CPUs), microprocessor units (MPUs), digital signal processors (DSPs), or other computing apparatuses well-known to those of ordinary skill in the art.

In this embodiment, the storage 115 of the testing apparatus 11 stores a test procedure TP, and the test procedure TP comprises three test items T1, T2 and T3 (which will be described in detail later). For example, the test procedure TP may be a test procedure designed for a certain model of touch mobile devices manufactured by a certain manufacturer. In addition, the storage 115 stores a piece of expected information I1 corresponding to the test item T1, a piece of expected information 12 corresponding to the test item T2, and a piece of expected information 13 corresponding to the test item T3 (which will be described in detail later). It is noted that the test procedure TP may be any test procedure that can automatically perform functional testing after being executed by the processor 117, and the way that the test procedure TP is obtained is not limited by the present invention. Please note that although the testing apparatus 11 of this embodiment stores only one test procedure and the test procedure comprises three test items, the number of test procedures that can be stored by the testing apparatus 11 as well as the number and types of test items that can be included by one test procedure are not limited by the present invention.

The processor 117 reads each of the test items T1, T2, and T3 comprised in the test procedure TP in order to perform functional testing on the touch mobile device 19. Generally speaking, for each of the test items T1, T2, and T3, the processor 117 determines a test result of the touch mobile device 19 regarding the test item according to a test datum received from the touch mobile device 19 through the transmission cable 12a by the transmission interface 111 and/or a feedback signal received from the motor controller 13 through the transmission cable 12b by the transmission interface 113 as well as the piece of expected information corresponding to the test item. In the following descriptions, how the testing apparatus 11 executes different types of test items T1, T2, and T3 and how to determine the test results of the touch mobile device 19 regarding the test items T1, T2, and T3 will be detailed.

In this embodiment, the test item T1 is a swipe test to a touch screen of the touch mobile device 19. The expected information I1 corresponding to the test item T1 comprises a piece of percentage information (not shown) and a display screen length (not shown) and a display screen width (not shown) of the model of touch mobile device manufactured by the manufacturer.

Specifically, when the testing apparatus 11 tests the touch mobile device 19 regarding the test item T1, the processor 117 reads the expected information I1 from the storage 115 and then calculates a piece of position information 50 according to the display screen length, the display screen width, and the percentage information comprised in the expected information I1. For ease of understanding, a specific example is provided herein, but it is not intended to limit the scope of the present invention. In this specific example, the percentage information comprised in the expected information I1 comprises a set of start point percentages (e.g., (10%, 20%), representing 10% of the width of the display screen and 20% of the length of the display screen) and a set of end point percentages (e.g., (10%, 50%), representing 10% of the width of the display screen and 50% of the length of the display screen), and the processor 117 calculates a start point position and an end point position as the position information 50 according to the display screen length, the display screen width, the set of start point percentages and the set of end point percentages.

Next, the testing apparatus 11 transmits the position information 50 (e.g., in the form of a G code control instruction) to the motor controller 13 through the transmission interface 113, and the motor controller 13 controls the X-axis motor 15a, the Y-axis motors 15b, and/or the Z-axis motor 15c to move according to the position information 50. Thereby, the stylus 17 is controlled to operate the touch mobile device 19. Thereafter, the transmission interface 113 receives a feedback signal FS1 from the motor controller 50, and the processor 117 determines the test result (not shown) of the touch mobile device 19 regarding the test item T1 according to the feedback signal FS1. In some embodiments, the expected information I1 corresponding to the test item T1 also comprises an expected result, and the processor 117 determines the test result of the touch mobile device 19 regarding the test item T1 by determining whether the feedback signal FS1 meets the expected result in the expected information I1. If the feedback signal FS1 meets the expected result in the expected information I1 (e.g., the feedback signal FS1 represents an idle state and the idle state is the expected result), the touch mobile device 19 passes the test of the test item T1. If the feedback signal FS1 does not meet the expected result in the expected information I1, the touch mobile device 19 fails the test of the test item T1.

In this embodiment, the test item T2 tests whether the image displayed by the touch mobile device 19 contains a preset image. The expected information 12 corresponding to the test item T2 comprises a preset image (not shown) to be determined. Specifically, when the testing apparatus 11 tests the touch mobile device 19 regarding the test item T2, the transmission interface 111 receives a test datum 52 from the touch mobile device 19, the processor 117 reads the preset image comprised in the expected information 12 from the storage 115, and the processor 117 compares a test image (not shown) corresponding to the test datum 52 with the preset image to determine the test result of the touch mobile device 19 regarding the test item T2. If the test image comprises the preset image, the touch mobile device 19 passes the test of the test item T2. If the test image does not comprise the preset image, the touch mobile device 19 fails the test of the test item T2.

In some embodiments, the touch mobile device 19 supports the Mobile High-Definition Link (MHL). For those embodiments, the testing apparatus 11 further comprises an image capture card (not shown) that is electrically connected to the transmission interface 111 and the processor 117, and the image capture card retrieves the test image from the test datum 52. In some other embodiments, the touch mobile device 19 does not support the Mobile High-Definition Link. For those embodiments, the processor 117 retrieves the test image from the test datum 52 by an Android debugging bridge (not shown).

In this embodiment, the test item T3 is a touch test to the touch screen of the touch mobile device 19. The expected information 13 corresponding to the test item T3 comprises a preset image as well as a display screen length (not shown) and a display screen width (not shown) of the model of touch mobile device manufactured by the manufacturer.

Specifically, when the testing apparatus 11 tests the touch mobile device 19 regarding the test item T3, the transmission interface 111 receives a test datum 54 from the touch mobile device 19, the processor 117 reads the preset image comprised in the expected information 13 from the storage 115, the processor 117 compares the test image corresponding to the test datum 54 (the test image) with the preset image to generate a piece of first position information (i.e., the position of the preset image in the test image), and then the processor 117 calculates a piece of second position information 56 (i.e., a touch range) according to the display screen length, the display screen width, and the first position information. Thereafter, the transmission interface 113 transmits the second position information 56 to the motor controller 13, and the motor controller 13 controls the X-axis motor 15a, the Y-axis motors 15b, and/or the Z-axis motor 15c to move according to the second position information 56. In this way, the stylus 17 is controlled to operate the touch mobile device 19.

Next, the transmission interface 113 receives a feedback signal FS2 from the motor controller 13, and the processor 117 then determines the test result (not shown) of the touch mobile device 19 regarding the test item T3 according to the feedback signal FS2. In some embodiments, the expected information 13 corresponding to the test item T3 also comprises an expected result, and the processor 117 determines the test result of the touch mobile device 19 regarding the test item T3 by determining whether the feedback signal FS2 meets the expected result. If the feedback signal FS2 meets the expected result in the expected information 13, the touch mobile device 19 passes the test of the test item T3. If the feedback signal FS2 does not meet the expected result in the expected information 13, the touch mobile device 19 fails the test of the test item T3.

Similarly, in some embodiments, the touch mobile device 19 supports the Mobile High-Definition Link. In these embodiments, the testing apparatus 11 further comprises an image capture card (not shown) electrically connected to the transmission interface 111 and the processor 117, and the image capture card retrieves the test image from the test datum 54. In some other embodiments, the touch mobile device 19 does not support the Mobile High-Definition Link. For those embodiments, the processor 117 retrieves the test image from the test datum 54 by an Android debugging bridge (not shown).

After the testing apparatus 11 completes the test procedure TP, the test of the touch mobile device 19 is completed. The testing apparatus 11 may output individual test results of the touch mobile device 19 regarding the test items T1, T2 and T3 (e.g., display the test results on the screen of the testing apparatus 11, record the test results in a test report) during or after the execution of the test procedure TP. It shall be noted that the way that the testing apparatus 11 outputs the test results is not limited by the present invention. After completing the test of the touch mobile device 19, the testing apparatus 11 may continue to test other touch mobile devices of the same brand and model with the test process TP, and this will not be further described herein.

In summary, the testing apparatus 11 tests the touch mobile device based on at least one test item comprised in a test procedure. For each test item included in a test procedure, the testing apparatus 11 determines the test result of the touch mobile device regarding the test item according to a piece of expected information corresponding to the test item and a test datum received from the touch mobile device and/or a feedback signal received from the motor controller. If the test result regarding whether the touch mobile device passes a test item has to be determined based on an image displayed by the touch mobile device, the testing apparatus 11 directly receives a test datum from the touch mobile device and then determines whether the touch mobile device passes the test item according to a test image corresponding to the test datum. The testing apparatus 11 does not require an external camera to capture an image regarding what is shown on the display of the touch mobile device, so the test result will not be affected by the light source of the testing environment. Hence, an accurate and stable test result can be achieved. In addition, the testing apparatus 11 can use the same test procedure to test other touch mobile devices of the same brand and model, hence automatic functional testing can be easily realized.

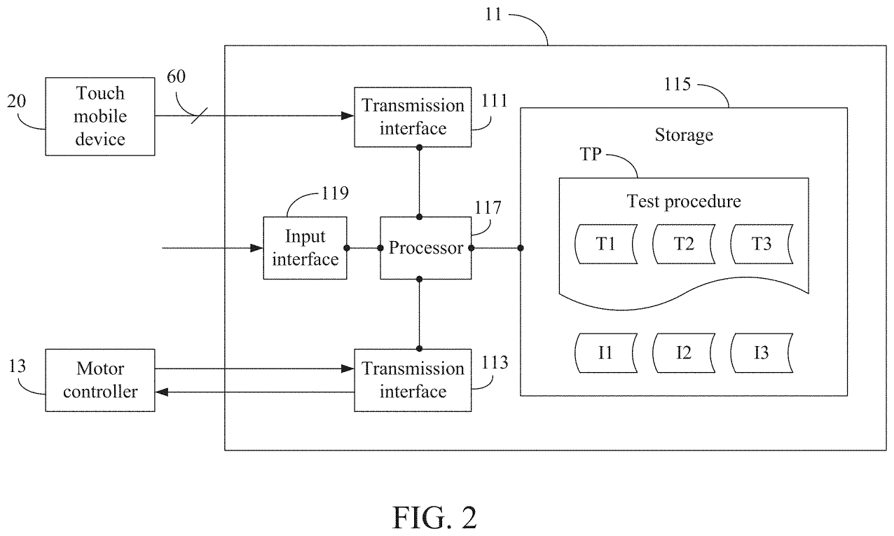

Please refer to FIG. 1A and FIG. 2 for a second embodiment of the present invention. As shown in FIG. 2, in this embodiment, the testing apparatus 11 further comprises one or more input interfaces 119 electrically connected to the processor 117 in addition to the transmission interfaces 111 and 113, the storage 115, and the processor 117. The input interface 119 may be any interface capable of receiving input information (e.g., a keyboard and a mouse, without being limited thereto). The second embodiment is an extension of the first embodiment. Specifically, in the second embodiment, the testing apparatus 11 further generates the test procedure TP through the following operations. The following description will be focused on the differences between the second embodiment and the first embodiment.

In this embodiment, the testing apparatus 11 has been installed an automated testing tool (e.g., a human-computer interaction intelligent robot software developed by IsCoolLab Co., Ltd., without being limited thereto), and the automated testing tool generates a test procedure for testing the touch mobile device based on the operation of users. The test procedure may be in the form of codes executable by a computer. Hereinafter, the test procedure TP will be taken as an example to describe its generation in detail.

The user executes the automated testing tool on the testing apparatus 11 and sequentially tests another touch mobile device 20 regarding the three test items T1, T2, and T3 through the automated testing tool. Since the user knows what the test items T1, T2, and T3 are, the user can generate the codes individually corresponding to the test items T1, T2, and T3 by using the automated testing tool and stores the codes individually corresponding to the test items T1, T2, and T3 in the storage 115 as the test procedure TP.

Specifically, for each of the test items T1, T2, and T3, the input interface 119 receives a test configuration (not shown). It shall be noted that the content of test configuration depends on the test item. In addition, if a test result regarding whether the touch mobile device passes a test item has to be determined based on an image displayed by the touch mobile device (for example, for the test item T2, it is tested whether the image displayed by the touch mobile device has a preset image), the transmission interface 111 receives a sample datum 60 from the touch mobile device 20 when testing the touch mobile device 20 regarding the test item. Next, the processor 117 generates at least one piece of expected information according to the sample datum 60 (e.g., retrieves a sample image from the sample datum 60 as the expected information by an image capture card or an Android debugging bridge). In some embodiments, the user may directly store a sample image in the testing apparatus 11 as the expected information. Thereafter, the processor 117 records in the storage 115 that the test item corresponds to the expected information. In some embodiments, the user may input the aforementioned preset image through the input interface 119.

If other information is required in order to determine whether the touch mobile device passes a test item, the user may input such information (e.g., a piece of percentage information, a display screen length, a display screen width) as the expected information through the input interface 119 when testing the touch mobile device 20 regarding that test item, and the processor 117 records in the storage 115 that the test item corresponds to the expected information input by the user.

According to the above descriptions, the testing apparatus 11 of the second embodiment provides a mechanism for users to generate a test procedure based on testing requirements thereof. In the stage of generating the test procedure, the testing apparatus 11 may receive the expected information corresponding to the test item(s) through the input interface 119 and/or receive the sample datum from a touch mobile device 20 through the transmission interface 111, and then generate the expected information according to the sample datum. Therefore, the testing apparatus 11 according to the second embodiment provides the user with a mechanism of conveniently generating a test procedure so that the automation of functional testing of the touch mobile device can be more easily realized.

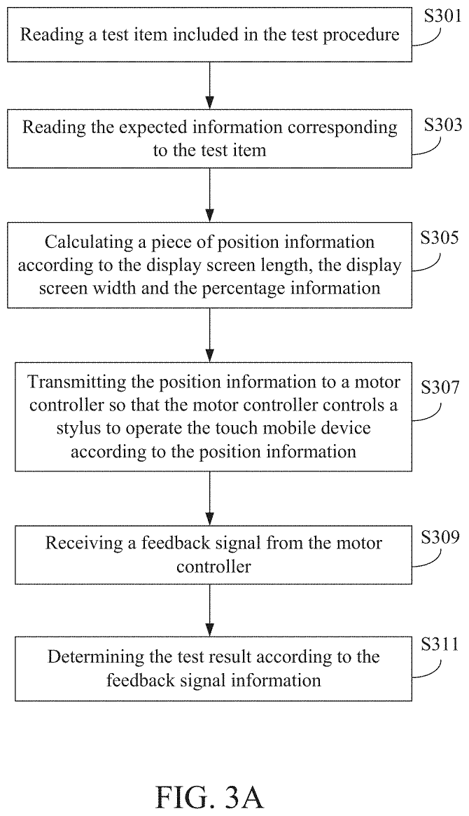

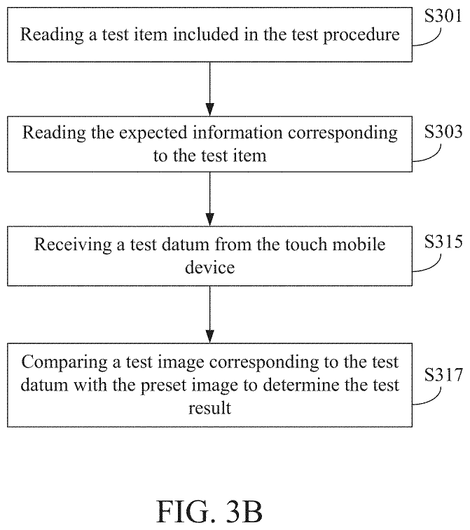

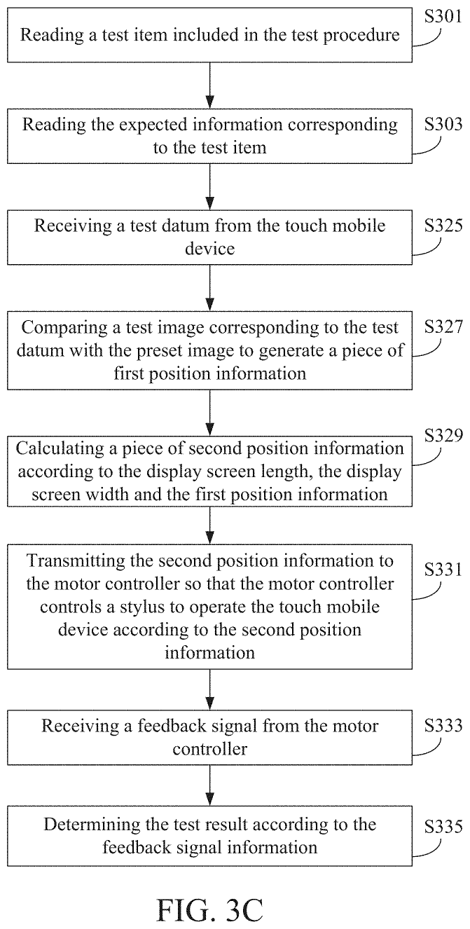

A third embodiment of the present invention is a testing method for testing a touch mobile device, and flowchart thereof are depicted in FIG. 3A to FIG. 3C. The testing method may be executed by an electronic computing apparatus (e.g. the aforesaid testing apparatus 11). The electronic computing apparatus stores a test procedure, wherein the test procedure comprises at least one test item. The electronic computing apparatus further stores a piece of expected information corresponding to each of the at least one test item.

In this embodiment, the testing method executes the procedure shown in FIG. 3A for some test items of the test procedure. Specifically, in step S301, the electronic computing apparatus reads a test item included in the test procedure. Next, in step S303, the electronic computing apparatus reads the expected information corresponding to the test item, wherein the expected information comprises a display screen length, a display screen width, and a piece of percentage information. Thereafter, in step S305, the electronic computing apparatus calculates a piece of position information according to the display screen length, the display screen width, and the percentage information. In step S307, the electronic computing apparatus transmits the position information to a motor controller so that the motor controller controls a stylus to operate the touch mobile device according to the position information. Then, in step S309, the electronic computing apparatus receives a feedback signal from the motor controller. In step S311, the electronic computing apparatus determines the test result according to the feedback signal.

In this embodiment, the testing method executes the procedure shown in FIG. 3B for some test items of the test procedure. Similarly, the testing method performs steps S301 and S303. However, please note that the expected information read in the step S303 comprises a preset image. Next, in step S315, the electronic computing apparatus receives a test datum from the touch mobile device. In step S317, the electronic computing apparatus compares a test image corresponding to the test datum with the preset image to determine the test result. In this embodiment, the testing method executes the procedure shown in FIG. 3C for some test items of the test procedure. Similarly, the testing method performs the steps S301 and S303. However, please note that the expected information read in the step S303 comprises a display screen length, a display screen width, and a preset image. Next, in step S325, the electronic computing apparatus receives a test datum from the touch mobile device. In step S327, the electronic computing apparatus compares a test image corresponding to the test datum with the preset image to generate a piece of first position information. In step S329, the electronic computing apparatus calculates a piece of second position information according to the display screen length, the display screen width, and the first position information.

In step S331, the electronic computing apparatus transmits the second position information to the motor controller so that the motor controller controls a stylus to operate the touch mobile device according to the second position information. In step S333, the electronic computing apparatus receives a feedback signal from the motor controller. Then, in step S335, the electronic computing apparatus determines the test result according to the feedback signal.

In addition to the aforesaid steps, the third embodiment can also execute all the operations and steps set forth in the first and second embodiments, have the same functions set forth in the first and second embodiments, and deliver the same technical effects as set forth in the first and second embodiments. How the third embodiment executes these operations and steps, has the same functions, and delivers the same technical effects as the first and second embodiments will be readily appreciated by those of ordinary skill in the art based on the explanation of the first and second embodiments, and thus will not be further described herein.

The testing method described in the third embodiment may be implemented as a computer program comprising a plurality of codes. The computer program is stored in a non-transitory tangible machine-readable medium. The non-transitory computer readable storage medium may be an electronic product, e.g., a read only memory (ROM), a flash memory, a floppy disk, a hard disk, a compact disk (CD), a digital versatile disc (DVD), a mobile disk, a database accessible to networks, or any other storage media with the same function and well known to those of ordinary skill in the art. After the codes of the computer program are loaded into an electronic computing apparatus (e.g., the testing apparatus 11), the computer program executes the testing method as described in the third embodiment.

It shall be noted that, in the specification of the present invention, terms “first” and “second” used in “the first position information” and “the second position information” are only used to mean that the aforesaid position information are different position information.

According to the above descriptions, the testing technology (including the apparatus, the system and the non-transitory tangible machine-readable medium thereof) for testing the touch mobile device provided by the present invention performs functional testing on a touch mobile device based on at least one test item included in a test procedure. For each test item included in a test procedure, the testing technology provided by the present invention determines a test result of the touch mobile device regarding the test item according to a piece of expected information corresponding to the test item and a test datum received from the touch mobile device and/or a feedback signal received from a motor controller.

If the test result regarding whether the touch mobile device passes a test item has to be determined based on an image displayed by the touch mobile device, the testing technology provided by the present invention directly receives a test datum from the touch mobile device and then determines whether the touch mobile device passes the test item according to a test image corresponding to the test datum. Since the testing technology provided by the present invention does not require an external camera to capture an image regarding what is shown on the display of the touch mobile device, the test result will not be affected by the light source of the testing environment. Therefore, an accurate and stable test result can be achieved. In addition, the testing technology provided by the present invention can use the same test procedure to test other touch mobile devices of the same brand and model, thus automatic functional testing of touch mobile devices can be easily realized.

The above disclosure is only utilized to enumerate some embodiments of the present invention and illustrated technical features thereof, which is not used to limit the scope of the present invention. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A testing apparatus, comprising:
a first transmission interface;
a second transmission interface;
a storage, storing a test procedure, wherein the test procedure comprises a test item and the storage further stores a piece of expected information corresponding to the test item; and
a processor, being electrically connected to the first transmission interface, the second transmission interface, and the storage and configured to read the test item of the test procedure,
wherein the processor determines a test result of a first touch mobile device regarding the test item according to the piece of expected information and at least one of a test datum received from the first touch mobile device by the first transmission interface and a feedback signal received from a motor controller by the second transmission interface.

2. The testing apparatus of claim 1, wherein the piece of expected information comprises a display screen length, a display screen width, and a piece of percentage information, and the testing apparatus determines the test result of the first touch mobile device regarding the test item by performing the following operations:
calculating, by the processor, a piece of position information according to the display screen length, the display screen width, and the piece of percentage information,
transmitting, by the second transmission interface, the piece of position information to the motor controller so that the motor controller controls a stylus to operate the first touch mobile device according to the piece of position information,
receiving, by the second transmission interface, the feedback signal from the motor controller, and
determining, by the processor, the test result according to the feedback signal.

3. The testing apparatus of claim 1, wherein the piece of expected information comprises a preset image, and the testing apparatus determines the test result of the first touch mobile device regarding the test item by performing the following operations:
receiving, by the first transmission interface, the test datum from the first touch mobile device, and
determining, by the processor, the test result by comparing a test image corresponding to the test datum with the preset image.

4. The testing apparatus of claim 3, wherein the first touch mobile device supports the Mobile High-Definition Link (MHL), the testing apparatus further comprises an image capture card, and the image capture card retrieves the test image from the test datum.

5. The testing apparatus of claim 3, wherein the first touch mobile device does not support the MHL, and the processor retrieves the test image from the test datum by an Android debugging bridge.

6. The testing apparatus of claim 1, wherein the piece of expected information comprises a display screen length, a display screen width, and a preset image, and the testing apparatus determines the test result of the first touch mobile device regarding the test item by performing the following operations:
receiving, by the first transmission interface, the test datum from the first touch mobile device,
deriving, by the processor, a piece of first position information by comparing a test image corresponding to the test datum with the preset image,
calculating, by the processor, a piece of second position information according to the display screen length, the display screen width, and the piece of first position information,
transmitting, by the second transmission interface, the piece of second position information to the motor controller so that the motor controller controls a stylus to operate the first touch mobile device according to the piece of second position information,
receiving, by the second transmission interface, the feedback signal from the motor controller, and
determining, by the processor, the test result according to the feedback signal.

7. The testing apparatus of claim 6, wherein the first touch mobile device supports the Mobile High-Definition Link (MHL), the testing apparatus further comprises an image capture card, and the image capture card retrieves the test image from the test datum.

8. The testing apparatus of claim 6, wherein the first touch mobile device does not support the MHL, and the processor retrieves the test image from the test datum by an Android debugging bridge.

9. The testing apparatus of claim 1, further comprising:
at least one input interface, being configured to receive a test configuration corresponding to the test item,
wherein regarding the test configuration, the first transmission interface receives a sample datum from a second touch mobile device, the processor generates the piece of expected information according to the sample datum, and the processor records that the test item corresponds to the piece of expected information.

10. A testing system, comprising:
a motor controller;
a testing apparatus, storing a test procedure, wherein the test procedure comprises a test item and the testing apparatus further stores a piece of expected information corresponding to the test item; and
a first transmission cable, being configured to connect the testing apparatus and a first touch mobile device; and
a second transmission cable, being configured to connect the testing apparatus and the motor controller;
wherein the testing apparatus reads the test item of the test procedure, and the testing apparatus determines a test result of the first touch mobile device regarding the test item according to the piece of expected information and at least one of a test datum received from the first touch mobile device and a feedback signal received from a motor controller.

11. The testing system of claim 10, wherein the piece of expected information comprises a display screen length, a display screen width, and a piece of percentage information, and the testing apparatus determines the test result of the first touch mobile device regarding the test item by performing the following operations:
calculating a piece of position information according to the display screen length, the display screen width, and the piece of percentage information,
transmitting the piece of position information to the motor controller so that the motor controller controls a stylus to operate the first touch mobile device according to the piece of position information,
receiving the feedback signal from the motor controller, and
determining the test result according to the feedback signal.

12. The testing system of claim 10, wherein the piece of expected information comprises a preset image, and the testing apparatus determines the test result of the first touch mobile device regarding the test item by performing the following operations:
receiving the test datum from the first touch mobile device, and
determining the test result by comparing a test image corresponding to the test datum with the preset image.

13. The testing system of claim 12, wherein the first touch mobile device supports the MHL, and the testing apparatus retrieves the test image from the test datum by an image capture card.

14. The testing system of claim 12, wherein the first touch mobile device does not support the MHL, and the testing apparatus retrieves the test image from the test datum by an Android debugging bridge.

15. The testing system of claim 10, wherein the piece of expected information comprises a display screen length, a display screen width, and a preset image, and the testing apparatus determines the test result of the first touch mobile device regarding the test item by performing the following operations:
receiving the test datum from the first touch mobile device,
deriving a piece of first position information by comparing a test image corresponding to the test datum with the preset image,
calculating a piece of second position information according to the display screen length, the display screen width, and the piece of first position information,
transmitting the piece of second position information to the motor controller so that the motor controller controls a stylus to operate the first touch mobile device according to the piece of second position information,
receiving the feedback signal from the motor controller, and
determining the test result according to the feedback signal.

16. The testing system of claim 15, wherein the first touch mobile device supports the MHL, and the testing apparatus retrieves the test image from the test datum by an image capture card.

17. The testing system of claim 15, wherein the first touch mobile device does not support the MHL, and the testing apparatus retrieves the test image from the test datum by an Android debugging bridge.

18. The testing system of claim 10, wherein the testing apparatus further receives a test configuration corresponding to the test item and performs the following operations regarding the test configuration:
receiving a sample datum from a second touch mobile device,
generating the piece of expected information according to the sample datum, and
recording that the test item corresponds to the pieced of expected information.

19. A non-transitory tangible machine-readable medium, storing a computer program comprising a plurality of codes, the codes being able to perform a testing method when the computer program is loaded into an electronic computing apparatus, the electronic computing apparatus storing a test procedure, the test procedure comprising a test item, the electronic computing apparatus further storing a piece of expected information corresponding to the test item, the testing method comprising the following steps:
reading the test item of the test procedure; and
determining a test result of a first touch mobile device regarding the test item according to the piece of expected information and at least one of a test datum received from the first touch mobile device by the electronic computing apparatus and a feedback signal received from a motor controller by the electronic computing apparatus.

20. The non-transitory tangible machine-readable medium of claim 19, wherein the piece of expected information comprises a display screen length, a display screen width, and a piece of percentage information, and the step of determining the test result comprises the following steps:
calculating a piece of position information according to the display screen length, the display screen width, and the piece of percentage information;
transmitting the piece of position information to the motor controller so that the motor controller controls a stylus to operate the first touch mobile device according to the piece of position information;
receiving the feedback signal from the motor controller; and
determining the test result according to the feedback signal.

21. The non-transitory tangible machine-readable medium of claim 19, wherein the piece of expected information comprises a preset image, and the step of determining the test result comprises the following steps:
receiving the test datum from the first touch mobile device; and
determining the test result by comparing a test image corresponding to the test datum with the preset image.

22. The non-transitory tangible machine-readable medium of claim 19, wherein the piece of expected information comprises a display screen length, a display screen width, and a preset image, and the step of determining the test result comprises the following steps:
receiving the test datum from the first touch mobile device;
deriving a piece of first position information by comparing a test image corresponding to the test datum with the preset image;
calculating a piece of second position information according to the display screen length, the display screen width, and the piece of first position information;
transmitting the piece of second position information to the motor controller so that the motor controller controls a stylus to operate the first touch mobile device according to the piece of second position information;
receiving the feedback signal from the motor controller; and
determining the test result according to the feedback signal.
